(19) United States
(12) Patent Application Publication
(10) Pub. No.: US 2010/0073132 A1
(43) Pub. Date: Mar. 25, 2010

(54) IGNITION SYSTEM FOR A VEHICLE

(75) Inventors: Ronald H. Dybalski, Oxford, MI (US); Frederick J. Berg, Auburn, MI (US); Timothy J. Bennett, Kawkawlin, MI (US); Richard A. Nash, Frankenmuth, MI (US)

Correspondence Address: HOWARD & HOWARD ATTORNEYS PLLC, 450 West Fourth Street, Royal Oak, MI, 48067, US

(73) Assignee: DELPHI TECHNOLOGIES, INC., Troy, MI (US)

(21) Appl. No.: 12/233,723

(22) Filed: Sep. 19, 2008

(51) Int. Cl. G06F 7/04; H05K 7/10

(52) U.S. Cl. 340/5.65; 361/679.31

(57) ABSTRACT

An ignition system for a vehicle includes an ignition port, a vehicle processor coupled to the ignition port and an engine of the vehicle and a portable ignition module. The portable ignition module includes a memory for storing data therein and a USB interface for engaging the ignition port. The portable ignition module stores a security code therein, that when transferred to the vehicle processor when the portable ignition module is inserted into the ignition port, enables operation of the vehicle. The portable ignition module includes an ignition switch and a touch screen display coupled to the ignition switch. An operator controls the vehicle by touching the touch screen display to activate the ignition switch, thereby signaling the processor to start and/or stop the engine.

### BACKGROUND OF THE INVENTION

1. Field of the Invention

The subject invention generally relates to an ignition system for a vehicle.

2. Description of the Prior Art

Many modern vehicles utilize electronic data, such as a security code, to enable an ignition system of the vehicle. The electronic data is often stored within a data chip disposed on a key. The key is then utilized to operate an ignition switch to control the operation of the vehicle, i.e., start and/or stop an engine.

With the advent of portable, large capacity memory storage devices, such as USB “flash drives” or “jump drives”, large amounts of data may be transferred between the memory storage device and the vehicle. For example, a security code for enabling operation of the vehicle may be stored on the memory storage device and transferred to the vehicle in order to enable operation of the vehicle.

U.S. Pat. No. 7,233,857 to Cahoon discloses an ignition system for a vehicle. The ignition system includes an ignition port. An on-board processor is coupled to the ignition port. A portable ignition module, having a memory for storing data therein, is insertable into the ignition port. The portable ignition module transfers data between the portable ignition module and the processor to enable operation of the engine. The portable ignition module is utilized in place of a traditional key to control the operation of the vehicle, i.e., start and/or stop an engine of the vehicle. As such, the vehicle must still utilize a traditional ignition switch commonly disposed within the steering column of the vehicle, in which the portable ignition module is utilized to rotate the standard ignition switch between the off, start and on positions. In addition, this arrangement requires the additional wiring needed to connect the portable ignition module to the processor.

### SUMMARY OF THE INVENTION AND ADVANTAGES

The subject invention provides an ignition system for a vehicle. The ignition system comprises an ignition port. A vehicle processor is coupled to the ignition port. The vehicle processor is configured for controlling an engine of the vehicle. A portable ignition module includes a memory for storing data therein. The portable ignition module is insertable into the ignition port for transferring data between the portable ignition module and the vehicle processor. The portable ignition module includes an ignition switch for signaling the vehicle processor to control the engine.

The subject invention also provides a method of operating an ignition system of a vehicle with a portable ignition module, the portable ignition module having a switch and the vehicle having an engine, an ignition port and a vehicle processor coupled to the ignition port and the engine. The method comprises the step of inserting the portable ignition module into the ignition port. The method further comprises the step of transferring data stored within the portable ignition module to the vehicle processor to enable operation of the engine. The method further comprises the step of actuating the switch on the portable ignition module to signal the vehicle processor to start the engine.

Accordingly, the ignition system of the subject invention utilizes an ignition switch within the portable ignition module to control the operation of the vehicle, i.e., starting and/or stopping the engine of the vehicle. Accordingly, the subject invention eliminates the need for the traditional barrel type ignition switch commonly disposed within the steering column of the vehicle and all manufacturing and production costs associated therewith.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a perspective view of a portable ignition module insertable into an ignition port disposed on a steering column of a vehicle; and

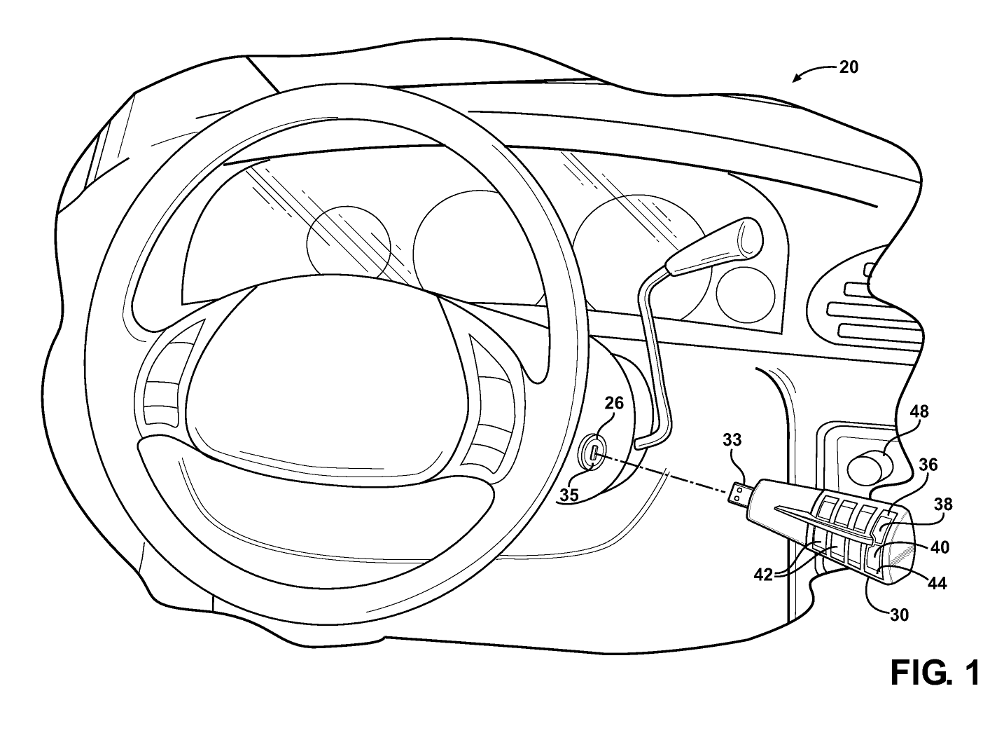

FIG. 2 is a schematic view of the vehicle.

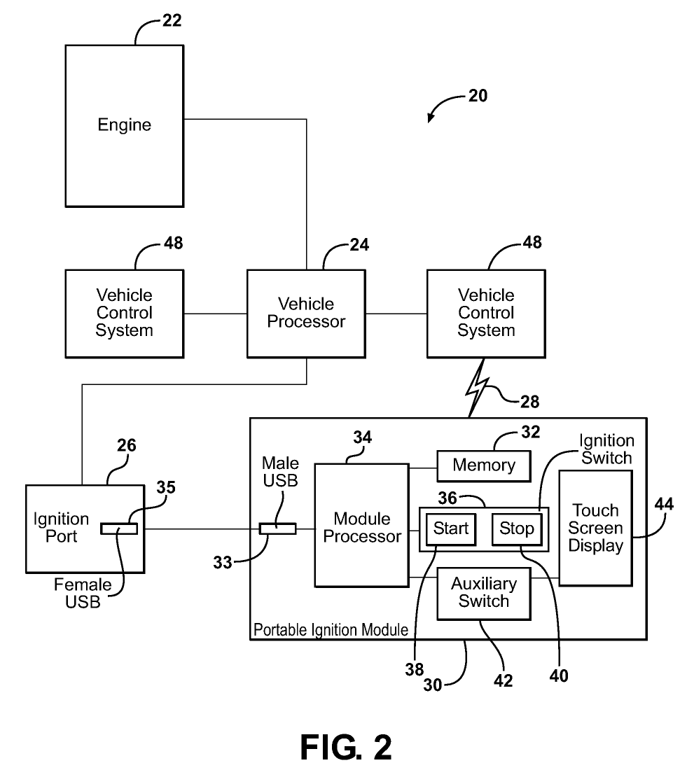

### DETAILED DESCRIPTION OF THE INVENTION

Referring to the Figures, wherein like numerals indicate corresponding parts throughout the several views, an ignition system is shown generally at 20. The ignition system 20 is for a vehicle, such as an automobile, truck, boat, ATV, etc., and controls the operation of an engine 22 of the vehicle. The engine 22 may comprise an internal combustion engine 22, an electric engine 22, or some other type of engine 22.

The ignition system 20 comprises a vehicle processor 24. The vehicle processor 24 is coupled to and configured for controlling the engine 22 of the vehicle. Accordingly, the vehicle processor 24 signals the engine 22 to activate, i.e., to start, and to deactivate, i.e., to stop. The vehicle processor 24 may include, for example, an on-board computer programmed to control the operation of the engine 22.

The ignition system 20 further comprises an ignition port 26. The ignition port 26 is coupled to the vehicle processor 24. The ignition port 26 is preferably located somewhere within the vehicle that is easily accessed by an operator of the vehicle. Accordingly, the ignition port 26 may be located on a steering column of the vehicle or on a dash of the vehicle. The ignition port 26 may be connected to the vehicle processor 24 via a hardwire connection to transmit data therebetween. Alternatively, the ignition port 26 may be connected to the vehicle processor 24 through a wireless communication system 28 capable of transmitting data therebetween.

The ignition system 20 further comprises a portable ignition module 30. The portable ignition module 30 includes a memory 32 for storing data therein. The portable ignition module 30 is insertable into the ignition port 26. When inserted into the ignition port 26, data is transferable between the portable ignition module 30 and the vehicle processor 24.

The data stored within the portable ignition module 30 may include a security code specific to the vehicle. The security code, once transferred to the vehicle processor 24, enables operation of the vehicle. Accordingly, once the portable ignition module 30 is inserted into the ignition port 26, data is transferred to the vehicle processor 24. If the vehicle is so equipped, the data may contain the security code authorizing use of the vehicle, and enabling the vehicle processor 24 to control the engine 22 if so signaled. It should be appreciated that the data stored within the memory 32 may include other information as well, such as operator preferences, audio and/or video entertainment files, etc.

The memory 32 of the portable ignition module 30 may include read and write capabilities. Accordingly, the vehicle processor 24 may not only read data stored within the memory 32 of the portable ignition module 30, but may write new data to the memory 32 of the portable ignition module 30. For example, if the portable ignition module 30 includes data representing the operator's preferences, this data may be updated or re-written to reflect a change in those preferences.

One of the ignition port 26 and the portable ignition module 30 includes a male interface 33, and the other of the ignition port 26 and the portable ignition module 30 includes a female interface 35. The female interface 35 mates with the male interface 33 to dock the portable ignition module 30 to the ignition port 26. Preferably, the male interface 33 includes a male USB interface, and the female interface 35 includes a female USB interface. However, it should be appreciated that the male interface and the female interface may include some other mating interface other than a USB interface.

The portable ignition module 30 includes an ignition switch 36. The ignition switch 36 is utilized for signaling the vehicle processor 24 to control the engine 22. The ignition switch 36 includes a start function 38 for signaling the vehicle processor 24 to activate the engine 22 of the vehicle, i.e., to start the engine 22. The ignition switch 36 further includes a stop function 40 for signaling the vehicle processor 24 to deactivate the engine 22 of the vehicle, i.e., to stop the engine 22 of the vehicle. The ignition switch 36 may include any suitable switch capable of signaling the vehicle processor 24 to activate and/or deactivate the engine 22, such as for example mechanical and/or electronic switches 42. Preferably, the ignition switch 36 includes a pressure sensitive electronic switch, which is activated by touching a sensor on the switch. Accordingly, the operator may engage the start function 38 by touching a first portion of the ignition switch 36 and may operate the stop function 40 by touching a second portion of the switch. It should be appreciated that the switch may include any suitable type, configuration and style of switch, and that the scope of the claims is not limited to that shown or described herein.

The portable ignition module 30 may include a touch screen display 44. The touch screen display 44 includes at least one image displayed on the touch screen display 44. The image represents a function that the operator may select, for example, the start function 38 and/or the stop function 40 of the ignition switch 36. Preferably, the touch screen display 44 is coupled to the ignition switch 36, with the touch screen display 44 being utilized to activate the ignition switch 36. The touch screen display 44 may include any suitable type of touch screen display 44, such as a small Liquid Crystal Display (“LCD”), typically a Thin Film Transistor (“TFT”) display. It should be appreciated that other types of touch screen displays 44 may also be utilized in the present invention. Preferably, the touch screen display 44 includes a flexible touch screen display 44 to allow the touch screen display 44 to flex as it is being activated, i.e., pressed. It should be appreciated that the touch screen display 44 and the ignition switch 36 may be integrally formed as a unitary sub-assembly.

The portable ignition module 30 may further include at least one auxiliary switch 42. The auxiliary switch 42 is utilized to signal the vehicle processor 24 to control a vehicular control system 48 of the vehicle. The vehicular control system 48 may include one or more vehicle control systems 48 chosen from a group of vehicular control systems 48 comprising: a vehicular door lock system, a vehicular alarm system, a vehicular lighting system, a vehicular cruise control system, a vehicular audio system, a vehicular video system, a vehicular driver preferences system and a vehicular windshield wiper system. It should be appreciated that the list of vehicle control systems 48 is not exclusive, and may include other vehicle control systems 48 not described herein.

The touch screen display 44 may include a plurality of screens, with each of the plurality of screens coupled to one of the at least one auxiliary switches 42. Accordingly, the portable ignition module 30 may include several auxiliary switches 42 and the touch screen display 44 may include several screens, with each screen coupled to one of the auxiliary switches 42. It should be appreciated that the touch screen display 44 may include one physical screen having several distinct areas to define the plurality of touch screen displays 44. Alternatively, it should be appreciated that the portable ignition module 30 may include a plurality of individual touch screen displays 44 to define the plurality of touch screen displays 44. It should also be appreciated that the auxiliary switches 42 and the plurality of touch screen displays 44 may all be integrally assembled into the unitary sub-assembly.

Each of the plurality of touch screen displays 44 includes an image representing the vehicular control system 48 coupled via one of the auxiliary switches 42 to that specific touch screen display 44. For example, one of the touch screen displays 44 may include an image of a windshield wiper, and that specific touch screen display 44 is coupled to one of the auxiliary switches 42 coupled to the vehicle windshield wiper control system 48. As such, the operator may select the touch screen display 44 showing an image of the wiper to activate the auxiliary switch 42 controlling the vehicular windshield wiper system 20. It should be appreciated that the image displayed will represent the vehicular control system 48 coupled that specific touch screen display 44.

The portable ignition module 30 includes a module processor 34 coupled to the touch screen display 44 for operating the touch screen display 44. If the touch screen display 44 includes a plurality of touch screen displays 44, then the module processor 34 is coupled to each of the plurality of touch screen displays 44. The module processor 34 is in communication with the memory 32 of the portable ignition system 20, as well as in communication with the vehicle processor 24 when the portable ignition module 30 is inserted into the ignition port 26. The module processor 34 may also be in communication with each of the auxiliary switches 42. The module processor 34 may include any type and/or configuration of processor suitable sized to fit within the portable ignition module 30.

The portable ignition module 30 may include a wireless communication system 28 in communication with the vehicle. The wireless communication system 28 may be utilized to operate at least one vehicular control system 48 of the vehicle. For example, the portable ignition module 30 may include an auxiliary switch 42 utilized for operating a vehicle door lock system 20 of the vehicle. As such, the operator my activate the appropriate auxiliary switch 42 for the vehicle door lock system 20 to lock and unlock the doors of the vehicle, without the portable ignition module 30 being inserted within the ignition port 26.

The subject invention also provides a method of operating an ignition system 20 of a vehicle. The method comprises the step of inserting the portable ignition module 30 into the ignition port 26. As described above, the ignition port 26 and the portable ignition module 30 comprise a USB interface. The portable ignition module 30 is therefore connected to the vehicle processor 24 once inserted into the ignition port 26, thereby allowing data transfer between the portable ignition module 30 and the vehicle processor 24.

The method further comprises the step of transferring data stored within the portable ignition module 30 to the vehicle processor 24 to enable operation of the engine 22. As described above, if the vehicle is so equipped, the data stored within the memory 32 of the portable ignition module 30 may include a specific security code. Once inserted into the ignition port 26, the security code may be transferred to the vehicle processor 24 to enable operation of the engine 22.

The method further comprises the step of actuating the ignition switch 36 on the portable ignition module 30 to signal the vehicle processor 24 to start the engine 22. As described above, the ignition switch 36 is preferably coupled to a pressure sensitive touch screen display 44. Accordingly, the operator simply touches the image on the touch screen display 44 representing the start function 38 to signal the vehicle processor 24 to start the engine 22. The vehicle processor 24 then signals the engine 22 to engage. Thus it should be appreciated that the ignition system 20 need not utilize any moving parts within the vehicle to start the engine 22, i.e., no mechanical key style ignition system is required.

The method further comprises the step of actuating the ignition switch 36 on the portable ignition module 30 to signal the vehicle processor 24 to stop the engine 22. As described above, the ignition switch 36 is preferably coupled to a pressure sensitive touch screen display 44. Accordingly, the operator simply touches the image on the touch screen display 44 representing the stop function 40 to signal the vehicle processor 24 to stop the engine 22. The vehicle processor 24 then signals the engine 22 to disengage.

The invention has been described in an illustrative manner, and it is to be understood that the terminology which has been used is intended to be in the nature of words of description rather than of limitation. As is now apparent to those skilled in the art, many modifications and variations of the present invention are possible in light of the above teachings. It is, therefore, to be understood that within the scope of the appended claims, wherein reference numerals are merely for convenience and are not to be in any way limiting, the invention may be practiced otherwise than as specifically described.

What is claimed is:

1. An ignition system for a vehicle, said system comprising:
an ignition port;
a vehicle processor coupled to said ignition port and configured for controlling an engine of the vehicle;
a portable ignition module having a memory for storing data therein and insertable into said ignition port for transferring data between said portable ignition module and said vehicle processor;
said portable ignition module including an ignition switch for signaling said vehicle processor to control the engine.

2. A system as set forth in claim 1 wherein said portable ignition module includes a touch screen display including at least one image displayed on said touch screen display with said touch screen display coupled to said ignition switch for activating said ignition switch.

3. A system as set forth in claim 2 wherein said touch screen display includes a flexible touch screen display.

4. A system as set forth in claim 2 wherein said portable ignition module includes a module processor coupled to said touch screen display for operating said touch screen display.

5. A system as set forth in claim 4 wherein said module processor is in communication with said memory of said portable ignition system.

6. A system as set forth in claim 5 wherein said module processor is in communication with said vehicle processor.

7. A system as set forth in claim 2 wherein said ignition switch includes a start function for signaling said vehicle processor to activate the engine of the vehicle and further includes a stop function for signaling said vehicle processor to deactivate the engine of the vehicle.

8. A system as set forth in claim 2 wherein said portable ignition module includes at least one auxiliary switch for signaling said vehicle processor to control a vehicular control system of the vehicle.

9. A system as set forth in claim 8 wherein said at least on auxiliary switch controls a vehicular control system of a group of vehicular control systems comprising: a vehicular door lock system, a vehicular alarm system, a vehicular lighting system, a vehicular cruise control system, a vehicular audio system, a vehicular video system, a vehicular driver preferences system and a vehicular windshield wiper system.

10. A system as set forth in claim 9 wherein said touch screen display includes a plurality of screens with each of said plurality of screens coupled to one of said at least one auxiliary switches.

11. A system as set forth in claim 10 wherein each of said plurality of touch screen displays includes an image representing a vehicular control system.

12. A system as set forth in claim 1 wherein one of said ignition port and said portable ignition module includes a male interface and the other of said ignition port and said portable ignition module includes a female interface for mating with said male interface.

13. A system as set forth in claim 12 wherein said male interface includes a male USB interface and said female interface includes a female USB interface.

14. A system as set forth in claim 1 wherein said memory of said portable ignition module includes read and write capabilities.

15. A system as set forth in claim 1 wherein said data stored within said portable ignition module includes a security code specific to the vehicle for enabling operation of the vehicle.

16. A system as set forth in claim 1 wherein said portable ignition module includes a wireless communication system in communication with the vehicle for operating at least one vehicular control system of the vehicle.

17. A system as set forth in claim 1 wherein said ignition switch includes a start function for signaling said vehicle processor to activate the engine of the vehicle and further includes a stop function for signaling said vehicle processor to deactivate the engine of the vehicle.

18. A system as set forth in claim 17 wherein said ignition switch is a pressure sensitive switch.

19. A portable ignition module for controlling an ignition system of a vehicle having an engine, an ignition port, and a vehicle processor coupled to the ignition port and the engine, said module comprising:
a memory for storing data therein;
an interface insertable into the ignition port for transferring data to and receiving data from the vehicle processor to enable operation of the engine; and
an ignition switch for signaling the vehicle processor to start the engine.

20. A system as set forth in claim 19 wherein said ignition switch includes a start function for signaling said vehicle processor to activate the engine of the vehicle and further includes a stop function for signaling said vehicle processor to deactivate the engine of the vehicle.

21. A system as set forth in claim 20 wherein said ignition switch is a pressure sensitive switch.

22. A system as set forth in claim 19 wherein said portable ignition module includes a touch screen display including at least one image displayed on said touch screen display with said touch screen display coupled to said ignition switch for activating said ignition switch.

23. A system as set forth in claim 22 wherein said portable ignition module includes at least one auxiliary switch for signaling said vehicle processor to control a vehicular control system of the vehicle.

24. A system as set forth in claim 23 wherein said touch screen display includes a plurality of screens with each of said plurality of screens coupled to one of said at least one auxiliary switches.

25. A system as set forth in claim 24 wherein each of said plurality of touch screen displays includes an image representing a vehicular control system.

26. A system as set forth in claim 22 wherein said portable ignition module includes a module processor coupled to said touch screen display for operating said touch screen display.

27. A method of operating an ignition system of a vehicle with a portable ignition module having a switch, the vehicle having an engine, an ignition port and a vehicle processor coupled to the ignition port and the engine, said method comprising the steps of:
inserting the portable ignition module into the ignition port;
transferring data stored within the portable ignition module to the vehicle processor to enable operation of the engine; and
actuating the switch on the portable ignition module to signal the vehicle processor to start the engine.

28. A method as set forth in claim 27 further comprising the step of actuating the switch on the portable ignition module to signal the vehicle processor to stop the engine.

29. A method as set forth in claim 28 wherein the portable ignition module includes a touch screen display and the step of actuating the switch on the portable ignition module is further defined as touching the touch screen display to actuate the switch on the portable ignition module.
